(19) United States
(12) Patent Application Publication
(10) Pub. No.: US 2026/0159951 A1
(43) Pub. Date: Jun. 11, 2026

(54) DEPOSITION EQUIPMENT WITH SHIELD COOLING DEVICE

(71) Applicant: SKYTECH INC., HSINCHU COUNTY (TW)

(72) Inventors: CHUN-FU WANG, HSINCHU COUNTY (TW); YAO-SYUAN CHENG, HSINCHU COUNTY (TW); CHI-HUNG CHENG, HSINCHU COUNTY (TW); CHI-HSIANG LIU, HSINCHU COUNTY (TW); KUO-JU LIU, HSINCHU COUNTY (TW); CHING-LIANG YI, HSINCHU COUNTY (TW)

(21) Appl. No.: 18/982,806

(22) Filed: Dec. 16, 2024

(30) Foreign Application Priority Data
Dec. 6, 2024 (TW) 113147440

(51) Int. Cl. C23C 16/46; C23C 16/458

(52) U.S. Cl. CPC C23C 16/463; C23C 16/4585

(57) ABSTRACT

The invention is a deposition equipment, which comprises a chamber, a shield, a fixing ring, a carrier, and a cooling device. One end of the shield is connected to the chamber, while the other end supports the fixing ring. The carrier is used to support a wafer. The carrier is located below the fixing ring and can drive the supported wafer to displace relative to the fixing ring and the shield. The cooling device is connected to the fixing ring, wherein the cooling device contains a cooling fluid and receives heat from the fixing ring through heat conduction to reduce the temperature of the fixing ring. By reducing the temperature of the fixing ring, the formation of a film at the interface between the fixing ring and the wafer can be avoided, and the adhesion between the fixing ring and the wafer can be effectively prevented.

### CROSS-REFERENCE TO RELATED APPLICATIONS

This non-provisional application claims priority claim under 35 U.S.C. § 119(a) on Taiwan Patent Application No. 113147440 filed Dec. 6, 2024, the entire contents of which are incorporated herein by reference.

### TECHNICAL FIELD

This invention is a deposition equipment with shield cooling device that effectively prevents adhesion between a fixing ring and a wafer during the deposition process.

### BACKGROUND

Chemical vapor deposition (CVD), physical vapor deposition (PVD), and atomic layer deposition (ALD) are commonly used deposition equipments, and are widely employed in the fabrication of integrated circuits, light-emitting diodes, and displays.

A deposition equipment mainly includes a chamber and a carrier, wherein the carrier is positioned within the chamber for carrying at least one wafer. For example in PVD, it is required to dispose a target in the chamber and have the target facing the wafer on the carrier. When performing the PVD, the wafer is fastened on the carrier by a holding device, then a inert gas and/or reactive gas may be transferred into the chamber, and then biases are respectively applied on the target and the carrier, moreover the carrier can also heat up the wafer carried thereby. The inert gas within the chamber is ionized by an effect of high-voltage electric field, such that to form ionized gas. Then, the ionized inert gas is attracted by the bias applied on the target to blast the target. On next, atoms or molecules flying out from the target are attracted by the bias on the carrier, and deposited on a surface of the heated-up wafer to form a thin film on the surface of the wafer.

During physical vapor deposition (PVD) or atomic layer deposition (ALD) processes, the demand for high throughput often necessitates prolonged and continuous deposition, subjecting internal chamber components to elevated temperatures for extended periods. When the temperature of these components reaches the melting point of the deposited metal, the metal may migrate to the interface between the component and the wafer, leading to adhesion and displacement of the wafer on the carrier. Consequently, subsequent wafer output may be compromised or the wafer may be damaged.

### SUMMARY

To address the limitations of prior art, this invention provides a novel deposition equipment with a shield cooling device. During the deposition process, the cooling device effectively reduces the temperature of internal chamber components, preventing adhesion between the wafer and these components.

One object of the invention is to provide a deposition equipment with shield cooling device, which comprises a chamber, a carrier, a fixing ring, a shielding device, and a cooling device. The carrier is configured to hold at least one wafer. One end of the shielding device is connected to the chamber, while the other end is used to support the fixing ring. As the carrier carrying the wafer moves towards the fixing ring, the fixing ring comes into contact with the wafer edge to secure the wafer on the carrier, forming a reaction space among the shielding device, fixing ring, carrier, and/or chamber.

The cooling device is in contact with the fixing ring and/or the shielding device, and contains a circulating cooling fluid. The cooling device is able to absorb heat from the fixing ring and/or the shielding device through thermal conduction, thereby reducing their temperatures and effectively preventing adhesion between the wafer and the fixing ring.

One object of the invention is to provide a deposition equipment with a shield cooling device. The cooling device is capable of continuously absorbing heat from the fixing ring and/or shielding device during the deposition process, thereby preventing excessive temperature rise of these components. By incorporating the cooling device, there is no need to interrupt the deposition process, and then the introduction of cooling gas into the chamber further reduces the temperature of internal components. Thus, the efficiency and throughput of the deposition process can be enhanced.

One object of the invention is to provide a deposition equipment with a shield cooling device, wherein the cooling fluid may be an inert gas or a non-reactive gas. Even if the cooling fluid leaks into the chamber, it will not contaminate the internal components or the wafer, thereby enhancing the safety of operation.

To achieve the foregoing objectives, this disclosure provides a deposition equipment with shield cooling device, which comprises a chamber, a shielding device, a fixing ring, a cooling device and a carrier. The chamber has a containment space. The shielding device is connected to the chamber and is located within the containment space of the chamber, wherein the shielding device includes an annular protrusion. The fixing ring is located within the containment space of the chamber and is disposed on the annular protrusion of the shielding device. The cooling device contacts with the fixing ring for reducing temperature of the fixing ring through a cooling fluid within the cooling device. The carrier is located within the containment space of the chamber and is disposed below the fixing ring, wherein the carrier is configured to support a wafer.

### BRIEF DESCRIPTION OF THE DRAWINGS

FIG. 1 is a cross-sectional view of a deposition equipment with a shield cooling device according to an embodiment of the invention.

FIG. 2 is a cross-sectional view of a deposition equipment with a shield cooling device operating in a loading or unloading state according to an embodiment of the invention.

FIG. 3 is a three-dimensional sectional view of part structures of a deposition equipment with a shield cooling device according to an embodiment of the invention.

FIG. 4 is a three-dimensional sectional view of a fixing ring and a cooling tube of a deposition equipment with a shield cooling device according to an embodiment of the invention.

FIG. 5 is a cross-sectional view of a fixing ring and a cooling tube of a deposition equipment with a shield cooling device according to another embodiment of the invention.

FIG. 6 is a cross-sectional view of a fixing ring and a cooling tube of a deposition equipment with a shield cooling device according to another embodiment of the invention.

### DETAILED DESCRIPTION

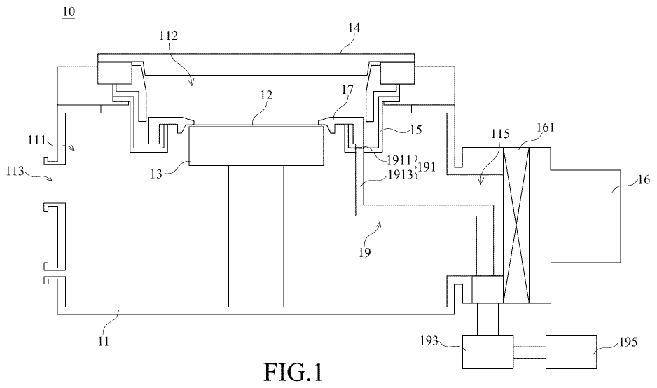

FIG. 1 is a cross-sectional view of a deposition equipment with shield cooling device according to an embodiment of the invention. The deposition equipment 10 with a shield cooling device mainly includes a chamber 11, a carrier 13, a shielding device 15, a fixing ring 17, and a cooling device 19. The shielding device 15 is used to support the fixing ring 17, and the carrier 13 is located below the fixing ring 17 and/or the shielding device 15. The carrier 13 can be used to drive a carried wafer 12 to displace relative to the fixing ring 17 and the shielding device 15.

In one embodiment of the invention, the cooling device 19 may include a cooling tube 191, a pump 193, and a cold tank 195. The chamber 11 has a containment space 111, and the carrier 13, the shielding device 15, the fixing ring 17, and the cooling tube 191 are disposed within the containment space 111 of the chamber 11.

The shielding device 15 includes a sidewall 151, an annular bottom 153, and an annular protrusion 155, wherein the annular bottom 153 connects the sidewall 151 and the annular protrusion 155. In one embodiment of the invention, the sidewall 151 of the shielding device 15 has an appearance similar to a hollow column or a hollow truncated cone, wherein one end of the sidewall 151 of the shielding device 15 is connected to the chamber 11 to dispose the shielding device 15 on the chamber 11, and the other end of the sidewall 151 is connected to the annular bottom 153.

The annular bottom 153 is substantially annular shape, with one end connected to the sidewall 151 of the shielding device 15. The annular protrusion 155 has an appearance similar to a hollow column or a hollow truncated cone. One end of the annular protrusion 155 is connected to the other end of the annular bottom 153, and a circular opening is formed on the radial inner side of the annular protrusion 155. Specifically, the sidewall 151 and the annular protrusion 155 are respectively connected to both ends of the annular bottom 153 and protrude or extend in the same direction. The annular protrusion 155 is located inside the sidewall 151, and the height and circumference of the sidewall 151 may be larger than those of the annular protrusion 155.

The fixing ring 17 includes a fixing part 171 and a shielding part 173. The fixing part 171 may be annular, the shielding part 173 has an appearance similar to a hollow column or a hollow truncated cone, and the shielding part 173 is annularly disposed around the annular fixing part 171.

The fixing ring 17 can be disposed on the shielding device 15. For example, the annular protrusion 155 of the shielding device 15 is used to connect and support the fixing part 171 of the fixing ring 17, wherein the shielding part 173 of the fixing ring 17 is located on the outer side of the annular protrusion 155 and between the annular protrusion 155 and the sidewall 151.

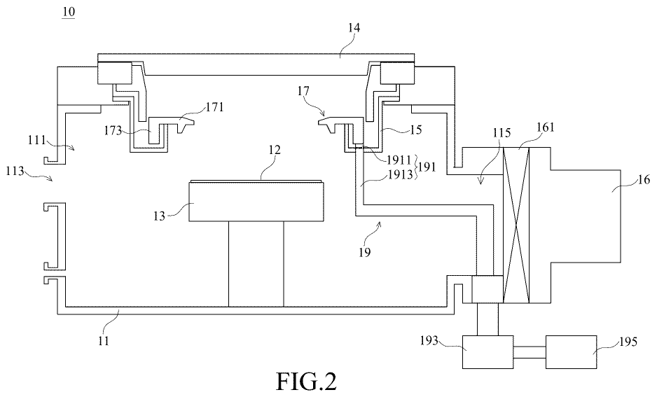

The carrier 13 is positioned below the fixing ring 17 and is used to support at least one wafer 12. The carrier 13 can drive the supported wafer 12 to displace relative to the fixing ring 17 and/or the shielding device 15. As shown in FIG. 2, a wafer passage 113 is provided on the chamber 11, wherein the carrier 13 can be displaced away from the fixing ring 17 and/or the shielding device 15 such that the height of the carrier 13 is approximately the same as that of the wafer passage 113. Then, a robotic arm may be used to place a wafer 12 from outside the chamber 11 onto the carrier 13 via the wafer passage 113, or to transport the wafer 12 on the carrier 13 from inside the chamber 11 to the outside via the wafer passage 113.

In one embodiment of the invention, the deposition equipment 10 with a shield cooling device may be a physical vapor deposition equipment, and a target 14 may be disposed in the chamber 11, wherein the target 14 faces the carrier 13 and/or the wafer 12. A vacuum outlet 115 is provided on the chamber 11, and a vacuum pump 16 is used to extract the gas in the chamber 11 through the vacuum outlet 115, so that the containment space 111 is at a low pressure or vacuum. A valve 161 can be disposed between the vacuum pump 16 and the containment space 111 of the chamber 11, and when the vacuum pump 16 extracts the gas in the chamber 11, the valve 161 can be closed.

A process gas can be supplied into the containment space 111 for a deposition process, such as an inert gas or a reactive gas. While the deposition equipment 10 with a shield cooling device is described as a physical vapor deposition equipment in one embodiment, this is merely an example and is not limitation of the invention. In other embodiments, the deposition equipment 10 with a shield cooling device may be an atomic layer deposition equipment or a plasma etching equipment.

As shown in FIG. 1, the carrier 13 can drive the supported wafer 12 to displace toward the fixing ring 17, the shielding device 15, and/or the target 14. Thus, the carrier 13 will be located on the inner side of the shielding device 15, and the fixing part 171 of the fixing ring 17 will contact the edge of the wafer 12 on the carrier 13 to secure the wafer 12 on the carrier 13. At this time, the carrier 13, the fixing ring 17, the shielding device 15, and the chamber 11 define a reaction space 112 within the containment space 111, and a thin film can be deposited on the surface of the wafer 12 within the reaction space 112. The reaction space 112 is substantially an isolated space within the containment space 111, wherein the reaction gas, target atoms, and/or target molecules within the reaction space 112 may not contact the chamber 11 outside the shielding device 15 to avoid depositing the thin film on the surface of the chamber 11, thereby preventing contamination of the chamber 11.

During the deposition process, the shielding device 15 and fixing ring 17 are subjected to high temperatures for an extended period, resulting in the deposition of a metal thin film on the surfaces of the wafer 12, shielding device 15, and fixing ring 17. When the temperature of the shielding device 15 and fixing ring 17 is greater than or equal to the melting point of the deposited metal, the deposited metal may flow between the fixing ring 17 and the wafer 12. For example, the deposited metal may flow from the fixing ring 17 to the wafer 12, resulting in the deposition of metal at the junction between the two.

As the temperature inside the chamber 11 decreases, the molten metal between the fixing ring 17 and the wafer 12 solidifies, causing the fixing ring 17 and the wafer 12 to adhere to each other. When the carrier 13 drives the wafer 12 to displace away from the fixing ring 17 and the shielding device 15, the fixing ring 17 will pull the wafer 12 through the solidified deposited metal, causing the wafer 12 to displace relative to the carrier 13, which in turn leads to abnormal positioning and transportation of the wafer 12. For example, the robotic arm may not be able to pick up the displaced wafer 12 on the carrier 13. Additionally, when the adhesion between the fixing ring 17 and the wafer 12 is severe, the solidified deposited metal between the fixing ring 17 and the wafer 12 may pull the wafer 12 more strongly, resulting in damage to the wafer 12 or the metal thin film on the surface of the wafer 12.

Taking a thick aluminum film as an example, the molten aluminum film may flow between the fixing ring 17 and the wafer 12, causing adhesion between the fixing ring 17 and the wafer 12. Additionally, during the deposition of the thick aluminum film, the temperature of the wafer 12 and the interior of the chamber 11 must be controlled within an appropriate range. However, during deposition, the plasma heats the fixing ring 17 and the shielding device 15 for an extended period, causing the temperature of the fixing ring 17 and the shielding device 15 to increase and store a significant amount of thermal energy. The high-temperature fixing ring 17 transfers heat to the wafer 12, causing the temperature of the wafer 12 edge to be excessively high, which not only causes the film deposited on the wafer 12 edge to become foggy but may also lead to whisker defects and hillock defects in the film deposited on the wafer 12 edge, resulting in non-uniform film deposition quality between the center and edge of the wafer 12.

To avoid the aforementioned problems, the deposition process is typically paused, and a cooling gas is introduced into the chamber 11 to reduce the temperature of the shielding device 15 and the fixing ring 17. Although this can reduce the non-uniformity of the film quality between the center and edge of the wafer 12, it also reduces the efficiency and throughput of the deposition process.

To effectively address the aforementioned issues, this invention provides a cooling device 19 disposed within the deposition equipment 10, wherein the cooling device 19 is in contact with the fixing ring 17, and the temperature of the fixing ring 17 is reduced through a cooling fluid within the cooling device 19.

In one embodiment of the invention, the cooling device 19 includes a cooling tube 191 and a pump 193, wherein the cooling tube 191 is disposed within the chamber 11 and is in contact with the fixing ring 17. The pump 193 is used to supply the cooling fluid to the cooling tube 191, whereby the cooling fluid reduces the temperature of the fixing ring 17 via the cooling tube 191.

The cooling device 19 may include a cold tank 195, wherein the cooling tube 191 is connected to the cold tank 195 via the pump 193. The pump 193 and the cold tank 195 are located outside the chamber 11, wherein the cold tank 195 is used to store or generate the cooling fluid, and the pump 193 is used to supply the cooling fluid from the cold tank 195 to the cooling tube 191. The cooling fluid may be an inert gas or a non-reactive gas, such as helium, argon, or nitrogen. In this way, even if the cooling fluid leaks from the cooling tube 191 into the containment space 111 of the chamber 11, it will not contaminate the chamber 11, the components inside the chamber 11, or the wafer 12.

The cold tank 195 may include a compressor. When the cooling fluid is in a gaseous state at room temperature, the cold tank 195 can compress and cool the gas into a liquid or a gas-liquid mixture, such as liquid helium, a helium gas-liquid mixture, liquid argon, an argon gas-liquid mixture, liquid nitrogen, or a nitrogen gas-liquid mixture. The pump 193 can supply the liquid or gas-liquid mixture of the cooling fluid to the cooling tube 191, allowing the liquid or gas-liquid mixture of the cooling fluid to absorb heat from the fixing ring 17 via the cooling tube 191 and convert into a gaseous cooling fluid.

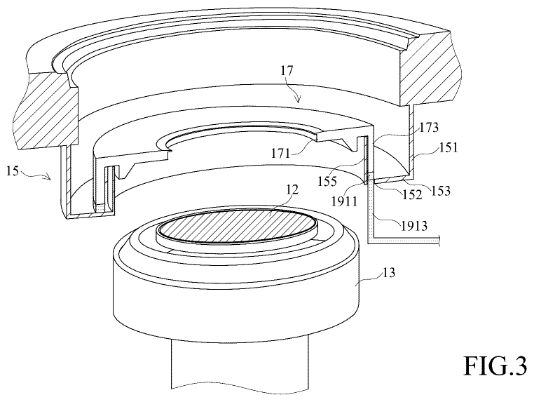

As shown in FIG. 3, in one embodiment of the invention, at least one perforation 152 may be provided on the shielding device 15. The cooling tube 191 may include an annular cooling tube 1911 and at least one transport tube 1913. The transport tube 1913 passes through the perforation 152 on the shielding device 15, and is connected to the annular cooling tube 1911 located on the other side of the shielding device 15. For example, the transport tube 1913 may pass through the perforation 152 located on the sidewall 151 or the annular bottom 153.

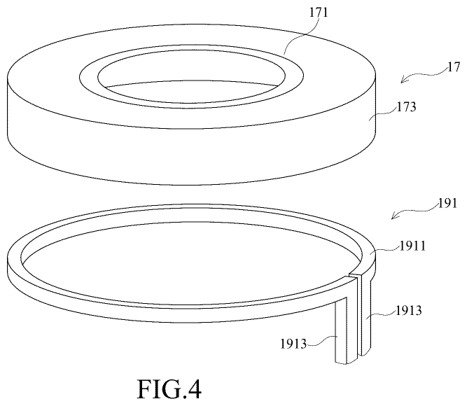

As shown in FIG. 4, in one embodiment of the invention, the cooling tube 191 may include an annular cooling tube 1911 and two transport tubes 1913, wherein the annular cooling tube 1911 is in contact with the fixing ring 17. The two transport tubes 1913 pass through the perforations 152 of the shielding device 15 and are connected to the annular cooling tube 1911, and one of the transport tubes 1913 is used to supply the cooling fluid to the annular cooling tube 1911. After passing through the annular cooling tube 1911, the cooling fluid exits the annular cooling tube 1911 via the other transport tube 1913. In practical applications, the cooling tube 191, the annular cooling tube 1911, and/or the transport tubes 1913 may be made of a metal with high thermal conductivity, such as a copper tube or a soft metal tube.

The annular cooling tube 1911 is similar in size and shape to the fixing ring 17. For example, the annular cooling tube 1911 and the shielding part 173 of the fixing ring 17 are substantially concentric rings in a top view. The shielding part 173 may be a hollow cylinder, while the annular cooling tube 1911 may be an annulus with a similar circumference, thereby increasing the contact area between the annular cooling tube 1911 and the shielding part 173 and facilitating heat transfer from the shielding part 173 and the fixing part 171 to the cooling fluid within the annular cooling tube 1911.

In one embodiment of the invention, the liquid or gas-liquid mixture of the cooling fluid can be delivered to the annular cooling tube 1911 via one of the transport tubes 1913. The liquid or gas-liquid mixture of the cooling fluid located within the annular cooling tube 1911 will absorb heat from the fixing ring 17 through thermal conduction to lower the temperature of the fixing ring 17. After absorbing heat, the liquid or gas-liquid mixture of the cooling fluid may be converted into a gaseous cooling fluid and exit the annular cooling tube 1911 via the other transport tube 1913. Additionally, the pump 193 can transport the gaseous cooling fluid to the cold tank 195, where the gaseous cooling fluid is compressed and cooled into a liquid or gas-liquid mixture by the cold tank 195, and then delivered to the annular cooling tube 1911 via the transport tube 1913, thereby reducing the temperature of the fixing ring 17 through circulating cooling fluid.

In one embodiment of the invention, the annular cooling tube 1911 may be positioned between the shielding device 15 and the fixing ring 17, and is in contact with both the shielding device 15 and the fixing ring 17 to reduce the temperature of the shielding device 15 and the fixing ring 17. For example, the annular cooling tube 1911 may be disposed on the annular bottom 153 of the shielding device 15, or between the annular bottom 153 and the annular protrusion 155. When the fixing ring 17 is placed on the annular protrusion 155 of the shielding device 15, the bottom portion of the shielding part 173 of the fixing ring 17 will be in contact with the annular cooling tube 1911.

In practical applications, the annular cooling tube 1911 of the cooling tube 191 is designed to cool the fixing ring 17 and/or the shielding device 15, while the transport tubes 1913 are used to convey the cooling fluid. For this purpose, the transport tubes 1913 and the annular cooling tube 1911 may be made of different materials, wherein the annular cooling tube 1911 may have a higher thermal conductivity than the transport tubes 1913. For example, the transport tubes 1913 may be made of a material with low thermal conductivity, while the annular cooling tube 1911 may be made of a material with high thermal conductivity. In another embodiment of the invention, the transport tube 1913 may be wrapped with a layer of insulation material.

To increase the contact area between the annular cooling tube 1911 and the fixing ring 17 and thus enhance the thermal conductivity between them, the top surface of the annular cooling tube 1911 may be configured to have a cross-sectional shape that is similar to or complementary to the bottom surface of the shielding part 173 of the fixing ring 17. As shown in FIG. 1, when the bottom surface of the shielding part 173 is flat, the top surface of the annular cooling tube 1911 can also be flat, allowing the bottom surface of the shielding part 173 to closely conform to the top surface of the annular cooling tube 1911.

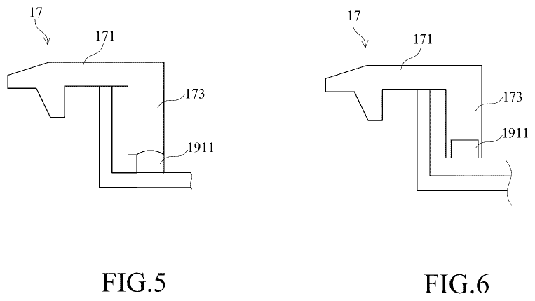

In other embodiment, as shown in FIG. 5, when the bottom surface of the shielding part 173 is concave or annularly recessed, the top surface of the annular cooling tube 1911 can be convex or annularly protruded, allowing the bottom surface of the shielding part 173 to conform to the top surface of the annular cooling tube 1911. Conversely, when the bottom surface of the shielding part 173 is convex or annularly protruded, the top surface of the annular cooling tube 1911 can be concave or annularly recessed.

In another embodiment, as shown in FIG. 6, the annular cooling tube 1911 may be positioned inside the fixing ring 17, and the transport tubes 1913 may be connected to the annular cooling tube 1911 located inside the fixing ring 17 to enhance heat transfer efficiency. For example, the annular cooling tube 1911 may be positioned within the shielding part 173 of the fixing ring 17.

The disclosed deposition equipment 10 with a shield cooling device can continuously absorb heat from the fixing ring 17 and/or the shielding device 15 through the cooling device 19 during the deposition process, thereby preventing the temperature of the fixing ring 17 and/or the shielding device 15 from becoming excessively high and reducing the formation of the metal film between the fixing ring 17 and the wafer 12. Furthermore, the implementation of the cooling device 19 allows for uninterrupted thin film deposition over extended periods, enhancing the efficiency and productivity of the deposition process.

The foregoing descriptions are merely preferred embodiments of this disclosure, and are not intended to limit the scope of this disclosure, that is, all equivalent changes and modifications made according to shapes, structures, features and spirits described in the scope of the claims of this disclosure shall fall within the scope of the claims of this disclosure.

What is claimed is:

1. A deposition equipment with shield cooling device, comprising:
a chamber having a containment space;
a shielding device connected to the chamber and located within the containment space of the chamber, wherein the shielding device includes an annular protrusion;
a fixing ring located within the containment space of the chamber and disposed on the annular protrusion of the shielding device;
a cooling device in contact with the fixing ring, and reducing temperature of the fixing ring through a cooling fluid within the cooling device; and
a carrier located within the containment space of the chamber and disposed below the fixing ring, wherein the carrier is configured to support a wafer.

2. The deposition equipment as claimed in claim 1, wherein the cooling device includes a cooling tube and a pump, wherein the cooling tube is in contact with the fixing ring, and the pump is configured to deliver the cooling fluid to the cooling tube.

3. The deposition equipment as claimed in claim 2, wherein the shielding device includes at least one perforation, and the cooling tube passes through the perforation and is in contact with the fixing ring.

4. The deposition equipment as claimed in claim 3, wherein the cooling tube comprises an annular cooling tube and two transport tubes, wherein the annular cooling tube is in contact with the fixing ring, and the cooling fluid is delivered to the annular cooling tube via one of the transport tubes and exits the annular cooling tube via the other transport tube.

5. The deposition equipment as claimed in claim 4, wherein the annular cooling tube of the cooling tube is disposed on the shielding device and is in contact with both the shielding device and the fixing ring, and the transport tubes of the cooling tube pass through the perforation of the shielding device and are connected to the annular cooling tube.

6. The deposition equipment as claimed in claim 4, wherein the annular cooling tube is disposed within the fixing ring.

7. The deposition equipment as claimed in claim 2, wherein the shielding device includes a side wall and an annular bottom, wherein the side wall is connected to the chamber, and the annular bottom is connected to both the side wall and the annular protrusion, wherein the annular protrusion is disposed on an inner side of the side wall and is configured to support the fixing ring.

8. The deposition equipment as claimed in claim 7, wherein the fixing ring includes a fixing part and a shielding part, wherein the annular protrusion of the shielding device is configured to support the fixing part of the fixing ring, and the shielding part of the fixing ring is located between the side wall and the annular protrusion of the shielding device.

9. The deposition equipment as claimed in claim 8, wherein the cooling tube includes an annular cooling tube and at least one transport tube, and the annular cooling tube is connected to the transport tube and is in contact with the shielding part of the fixing ring.

10. The deposition equipment as claimed in claim 1, wherein the cooling fluid is an inert gas or a non-reactive gas.
